(19) United States
(12) Patent Application Publication
(10) Pub. No.: US 2026/0260047 A1
(43) Pub. Date: Sep. 3, 2026

(54) RE-USE AWARE ROUTING

(71) Applicant: International Business Machines Corporation, Armonk, NY (US)

(72) Inventors: Jesse Peter Surprise, Highland, NY (US); Genevieve Shafer, Poughkeepsie, NY (US); William Edward Dougherty, JR., Pittsburgh, PA (US); Stephan Held, Niederkassel (DE); Fine Foos, Viersen (DE); Eduard Herkel, Stuttgart (DE)

(21) Appl. No.: 19/066,624

(22) Filed: Feb. 28, 2025

(51) Int. Cl. G06F 30/32

(52) U.S. Cl. CPC G06F 30/32

(57) ABSTRACT

A method of re-use aware routing for an integrated circuit (IC) design is provided. The method includes identifying logical continent blocks disposable in a defined area at a hierarchical level and having a common logical layout, disposing the logical continent blocks at the hierarchical level and in the defined area, determining port intervals for the logical continent blocks, executing a first routing pass through the port intervals, choosing leader and non-leader logical continent blocks, copying a point where the first routing pass crosses a border of the leader logical continent block into the non-leader logical continent block and executing a second routing pass for a net to cross the point for each logical continent block.

### BACKGROUND

The present disclosure generally relates to semiconductor electronic design automation (EDA). More specifically, the present disclosure relates to semiconductor EDA employing re-use aware routing.

EDA involves the use of software tools for designing electronic systems such as integrated circuits (ICs) and printed circuit boards. One aspect of design is timing: generally, ICs have data signals and a clock. The data signal needs to reach a certain node at the correct time vis-a-vis the time when the corresponding clock cycles the device at that node. If the data signal does not arrive in time, the clock is too fast, or alternatively, the data signal is taking too long to propagate (path is too slow).

Another aspect of design is placement: based on a logical description, each component is placed, looking to minimize congestion in each area of the design. In modern very large scale integration (VLSI) designs, large parts of the design must typically be placed and optimized in a hierarchical manner. Current techniques for such physical hierarchy may have certain disadvantages, such as, for example, the need to create wiring contracts between levels of hierarchy in order to go over macros (in general, a chip may contain multiple sub-blocks termed cores, cores may be partitioned into sub-blocks termed units, and units may be partitioned into smaller sub-blocks termed macros); the need to use buffer bays to help traverse macros in order to repeat signals crossing hierarchies; and/or the need to use latch bays to help repeat pervasive signals crossing hierarchies.

When a lower level piece of hierarchy is required to be crossed, current techniques typically leave a “cutout” or buffer bay to add a repeater later at the upper level of hierarchy. Similarly, if there is not enough porosity of a given wiring layer, a wiring contract is established between the two layers. These issues tend to solidify the designs early-on and prohibit changes that may be more efficient, thereby disadvantageously freezing hierarchies of the design.

### SUMMARY

According to an aspect of the disclosure, a method of re-use aware routing for an integrated circuit (IC) design is provided. The method includes identifying logical continent blocks disposable in a defined area at a hierarchical level and having a common logical layout, disposing the logical continent blocks at the hierarchical level and in the defined area, determining port intervals for the logical continent blocks, executing a first routing pass through the port intervals, choosing leader and non-leader logical continent blocks, copying a point where the first routing pass crosses a border of the leader logical continent block into the non-leader logical continent block and executing a second routing pass for a net to cross the point for each logical continent block. This increases efficiency by allowing a logical continent block to be created once and re-used as many times as needed.

In accordance with one or more additional and/or alternative embodiments, the logical continent blocks form one of multiple mirrored logical continent block pairs of the IC design according to a user input.

In accordance with one or more additional and/or alternative embodiments, the determining of the port intervals is executed to force certain pin locations for the logical continent blocks to dictate subsequent net routing.

In accordance with one or more additional and/or alternative embodiments, the executing of the first routing pass includes computing connections through the port intervals in a way that will verify that the port intervals are placed correctly.

In accordance with one or more additional and/or alternative embodiments, the method further includes placing re-use blockages between the logical continent blocks and additional logical continent blocks to simplify net routing.

In accordance with one or more additional and/or alternative embodiments, each logical continent block includes a common gate and the method further includes mirroring locations of the common gate to improve routing.

In accordance with one or more additional and/or alternative embodiments, the mirroring of the locations of the common gate includes mirroring the location of the common gate in the leader logical continent block to the non-leader logical continent block to increase design efficiency.

In accordance with one or more additional and/or alternative embodiments, the mirroring of the locations of the common gate includes identifying a new position derived from initial positions of the common gate in each of the logical continent blocks and positioning the common gate at the new position in each of the logical continent blocks to increase design efficiency.

In accordance with one or more additional and/or alternative embodiments, the method further includes identifying the common gate based on a logical instance name thereof which is a straightforward solution in the design process.

In accordance with one or more additional and/or alternative embodiments, the method further includes identifying the common gate based on a user input which is a straightforward solution in the design process.

According to an aspect of the disclosure, an integrated circuit (IC) with re-use aware routing is provided and includes a hierarchical level having a defined area, logical continents at the hierarchical level and in the defined area, each having a common logical layout, additional logical continents, each having a distinct logical layout from the common logical layout and being disposed at the hierarchical level, re-use blocks between the logical continents and the additional logical continents, a net routed to each one of the logical continents and pins where the net crosses a boundary of each one of the logical continents. This increases efficiency by allowing a logical continent block to be created once and re-used as many times as needed.

In accordance with one or more additional and/or alternative embodiments, each one of the logical continents in a mirrored logical continent block pair with another one of the logical continents includes a common gate at a same relative position therein and a port interval at a same relative position therein, the net is routed between the common gate of each one of the logical continents in the mirrored logical continent block pair and the pins are located within the port interval of each one of the logical continents in the mirrored logical continent block pair to improve routing.

In accordance with one or more additional and/or alternative embodiments, the hierarchical level has at least first and second axes, which extend through the defined area and which are transverse with respect to one another and the logical continents are provided in at least first and second mirrored logical continent block pairs mirrored about the first and second axes, respectively, to allow for multiple options for mirroring.

According to an aspect of the disclosure, an integrated circuit (IC) design with re-use aware routing is provided and includes a hierarchical level having a defined area and an axis extending through the defined area and multiple logical continent blocks disposed at the hierarchical level and in the defined area, each one of the multiple logical continent blocks having a common logical layout and being mirrored with respect to another one of the multiple logical continent blocks about the axis. This increases efficiency by allowing a logical continent block to be created once and re-used as many times as needed.

In accordance with one or more additional and/or alternative embodiments, the IC design further includes additional logical continent blocks, each having a distinct logical layout from the common logical layout and being disposed at the hierarchical level and in the defined area between mirrored logical continent block pairs, and re-use blockages arranged between the multiple logical continent blocks and the additional logical continent blocks to provide for a complete IC design.

In accordance with one or more additional and/or alternative embodiments, each one of the multiple logical continent blocks in a mirrored logical continent block pair includes a gate at a same relative position therein and a port interval at a same relative position therein and the IC design further includes a net routed between the gate of each one of the multiple logical continent blocks in a mirrored logical continent block pair and pin locations defined within the port interval of each one of the multiple logical continent blocks in the mirrored logical continent block pair where the net crosses a boundary of each one of the multiple logical continent blocks in the mirrored logical continent block pair with improved routing.

In accordance with one or more additional and/or alternative embodiments, the hierarchical level has at least first and second axes, which extend through the defined area and which are transverse with respect to one another, and the multiple logical continent blocks are provided in at least first and second mirrored logical continent block pairs mirrored about the first and second axes, respectively, to allow for multiple options for mirroring.

According to an aspect of the disclosure, an integrated circuit (IC) design with re-use aware routing is provided and includes a hierarchical level having a defined area and multiple axes extending through the defined area and multiple logical continent blocks disposed at the hierarchical level and in the defined area, each one of the multiple logical continent blocks having a common logical layout and being mirrored with respect to another one of the multiple logical continent blocks about at least one of the multiple axes. This increases efficiency by allowing a logical continent block to be created once and re-used as many times as needed.

In accordance with one or more additional and/or alternative embodiments, the IC design further includes additional logical continent blocks, each having a distinct logical layout from the common logical layout and being disposed at the hierarchical level and in the defined area between mirrored logical continent block pairs, and re-use blockages arranged between the multiple logical continent blocks and the additional logical continent blocks to provide for a complete IC design.

In accordance with one or more additional and/or alternative embodiments, each one of the multiple logical continent blocks in a mirrored logical continent block pair includes a common gate at a same relative position therein and a port interval at a same relative position therein, and the IC design further includes a net routed between the common gate of each one of the multiple logical continent blocks in a mirrored logical continent block pair and pin locations defined within the port interval of each one of the multiple logical continent blocks in the mirrored logical continent block pair where the net crosses a boundary of each one of the multiple logical continent blocks in the mirrored logical continent block pair with improved routing.

In accordance with one or more additional and/or alternative embodiments, the multiple axes include at least first and second axes, which extend through the defined area and which are transverse with respect to one another, and the multiple logical continent blocks are provided in at least first and second mirrored logical continent block pairs mirrored about at least one of the first and second axes, respectively, to allow for multiple options for mirroring.

According to an aspect of the disclosure, a re-use aware routing method for an integrated circuit (IC) design is provided and includes defining a defined area of a hierarchical level of the IC design with an axis extending therethrough, identifying multiple logical continent blocks disposable at the hierarchical level and in the defined area and having a common logical layout and disposing the multiple logical continent blocks at the hierarchical level and in the defined area with each one of the multiple logical continent blocks having the common logical layout mirrored with respect to another one of the multiple logical continent blocks about the axis. This increases efficiency by allowing a logical continent block to be created once and re-used as many times as needed.

In accordance with one or more additional and/or alternative embodiments, the method further includes disposing additional logical continent blocks, which have a distinct logical layout from the common logical layout, at the hierarchical level and in the defined area between mirrored logical continent block pairs, and arranging re-use blockages between the multiple logical continent blocks and the additional logical continent blocks to provide for a complete IC design.

In accordance with one or more additional and/or alternative embodiments, each one of the multiple logical continent blocks in a mirrored logical continent block pair includes a common gate at a same relative position therein and a port interval at a same relative position therein, and the re-use aware routing method further includes routing a net between the common gate of each one of the multiple logical continent blocks in a mirrored logical continent block pair and defining pin locations within the port interval of each one of the multiple logical continent blocks in the mirrored logical continent block pair where the net crosses a boundary of each one of the multiple logical continent blocks in the mirrored logical continent block pair with improved routing.

In accordance with one or more additional and/or alternative embodiments, the hierarchical level has at least first and second axes, which extend through the defined area and which are transverse with respect to one another, and the re-use aware routing method further includes providing the multiple logical continent blocks in at least first and second mirrored logical continent block pairs mirrored about the first and second axes, respectively, to provide for multiple options for mirroring.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a schematic diagram of a computing environment for executing re-use aware routing for an IC design in accordance with one or more embodiments of the present invention;

FIG. 2 is a schematic diagram of an IC design without re-use aware routing;

FIG. 3 is a schematic diagram of an IC design with re-use aware routing in accordance with one or more embodiments of the present invention;

FIG. 4 is a schematic diagram of an IC with re-use aware routing in accordance with one or more embodiments of the present invention;

FIG. 5 is a schematic diagram of an IC design with multiple axes in accordance with one or more embodiments of the present invention;

FIG. 6 is a flow diagram illustrating a re-use aware routing method for an IC design in accordance with one or more embodiments of the present invention;

FIG. 7 is a flow diagram illustrating a method of re-use aware routing for an IC design in accordance with one or more embodiments of the present invention; and

FIG. 8 is a schematic diagram of a computing environment for executing re-use aware routing for an IC design without mirroring in accordance with one or more embodiments of the present invention.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

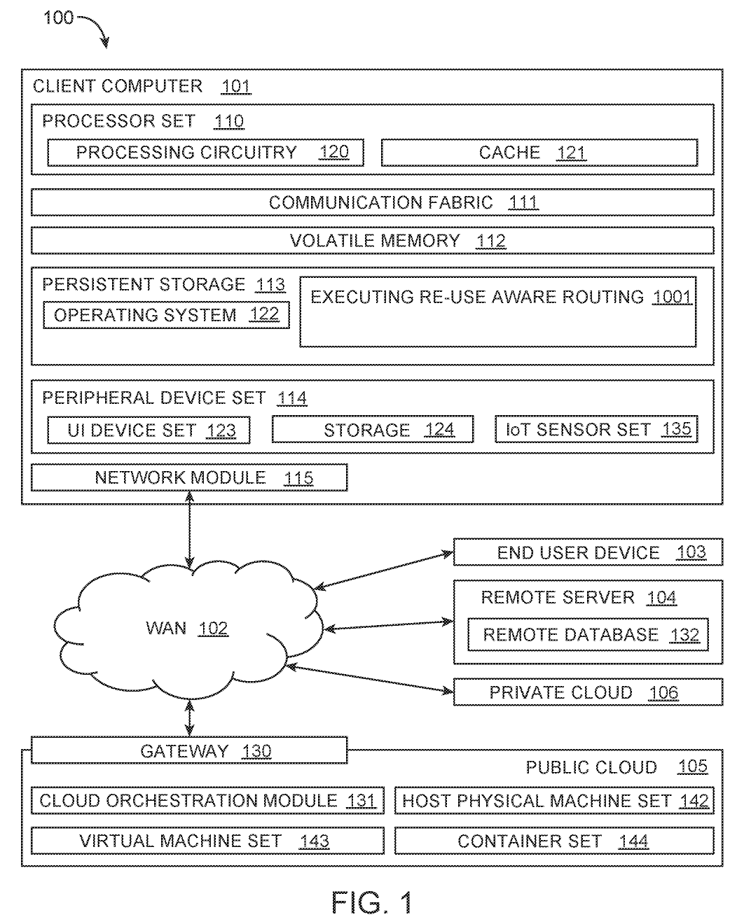

With reference to FIG. 1, a computer or computing device 100 that implements a computer-implemented method for executing re-use aware routing for an IC design is provided in accordance with one or more embodiments of the present invention is provided. The computer or computing device 100 of FIG. 1 contains an example of an environment for the execution of at least some of the computer code involved in performing the inventive methods, such as the block 1001 of the computer-implemented method for executing re-use aware routing for an IC design. In addition to the computer-implemented method for executing re-use aware routing for an IC design of block 1001, the computer or computing device 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and the computer-implemented method of block 1001, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

The computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of the computer-implemented method, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

The processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In the computer-implemented method, at least some of the instructions for performing the inventive methods may be stored in the block 1001 of the computer-implemented method in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input / output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in the block 1001 of the computer-implemented method typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud

For the sake of brevity, conventional fabrication techniques may or may not be described in detail herein. Moreover, the various tasks and process steps described herein can be incorporated into a more comprehensive procedure or process having additional steps or functionality not described in detail herein. In particular, various steps in the manufacture of certain types of devices are well known and so, in the interest of brevity, many conventional steps will only be mentioned briefly herein or will be omitted entirely without providing the well-known process details.

Turning now to an overview of technologies that are more specifically relevant to aspects of the disclosure, in modern VLSI designs, large parts of the design must typically be placed and optimized in a hierarchical manner. Accordingly, a flat design will ideally be split into different logical and physical partitions. These partitions will then be optimized in parallel and independent of each other. The design is often created in a high level description language (e.g., very high speed integrated circuit hardware description language (VHDL or VHSIC-HDL)) with a logical hierarchy description. This logical hierarchy description should have a physical hierarchy description that implements its function in terms of fitting each desired function to physical requirements that can be placed and routed to meet the timing constraints.

A design team typically starts with a bottoms-up approach implementing the small parts of the hierarchy and fitting them into larger partitions which are meant to fit into the core (of a microprocessor). The bottoms-up approach creates a small block floorplan. One pertinent challenge is to physically construct larger partitions which enclose the small blocks which are compacted (optimized for place and routing) through an hierarchical large block synthesis (HLBS) place and route methodology. These larger partitions typically require pin assignment and feedthrough generation such that the design flow is convergent. Routing at the top level of hierarchy is desired to be straight and non-detoured to achieve high-performance timing goals.

Current techniques for physical hierarchy employ a “hard” hierarchy, wherein design units are subdivided down as core, unit and random logic macro (RLM) with hard boundaries. A random logic macro is typically synthesized logic using a standard cell library; layout is performed with automated place and route tools. The core has units, and units have RLMs. The “hard” hierarchy introduces obstacles that are difficult to work around. The design team typically must create wiring contracts between levels of hierarchy in order to go over macros and can use buffer bays to help traverse macros in order to repeat signals crossing hierarchies and/or must use latch bays to avoid clutter and to help repeat pervasive signals crossing hierarchies.

A wiring stack can be arranged from lowest to highest layers: Ax, Bx, Cx, Dx. At the top level of the core, routing can be on Dx layers. The underlying RLMs can only use up to the C layer and cannot touch D. A unit can use D to route across, but beneath that layer of the physical hierarchy, there are lower blocks' RLMs. If the RLMs going in and out of that unit (or even within that unit from RLM to RLM contained therein) cannot complete routing (run out of resources), then part of Dx can be “opened up” to the lower levels of hierarchy (RLMs). Thus, some blockage goes to the parent and some to the child to subdivide the D layer between those levels of hierarchy. The wiring channels are limited and if they are all used up in one layer of hierarchy, and not in another, then they can be divided/shared.

At the lowest level of the hardware description language (HDL) description, physical representations are created and sized accordingly based on notions which can be placed and routed. The entire design can be flattened down to the leaf technology gates. The design is legally placed with a clustering that maintains the logical function from the HDL. The design is placed as tightly as possible to enable routing based on the given technology rules. From the flattened circuit representation, the small block place and route boundaries are extrapolated, and a small block floorplan is produced. In particular, the core can be defined by a physical placement/routing boundary, and can includes various physical circuits and/or technology gates. A clustering process results in a small block floorplan with small functional blocks including RLMs.

Now consider a large block abutted hierarchy. Using the small block floorplan, virtual partitions can be proposed for a large block floorplan (also called continents). These large virtual partitions can be fully abutted or partially abutted, leaving space at the top level of the hierarchy. In some instances, large block partitions use the HLBS process to achieve a high degree of area compaction to reduce power. Timing and routing congestion are checked against this to verify meeting those constraints.

Heretofore, HLBS has been used to construct large blocks. This achieves tight area compaction, power reduction, and timing closure. Typically, children macros (small blocks) and pre-synthesized and latch-to-latch paths are solved, a top-level is loaded, the pre-synthesized children are loaded in place (preplaced), boundaries of children are exposed to optimization and to hide internals and placement and timing closure with route-ability estimation are carried out.

In certain cases, top-level VHDL, a small block floorplan from a prior planning step and a proposed large block floorplan can be taken as inputs to output large block physical partitions (continents) with pin assignment enabling abutted routing (abstracts), an HDL logic description for large block physical partitions and timing assertions for large block physical partitions (continents). Port location and size can be optimized providing legally sized and placed pin assignment for all large block partitions at the boundary. Net and feedthrough topology can be optimized providing “no zig-zag” routing, straight abutment routes at the second level hierarchy and/or ensuring that nets that end in a partition do not go out and back into the same partition on the same signal net. Slack distribution can be performed for timing assertions and/or to generate directives in an aspect-oriented design tool for generating new continent VHDL. Such a tool can, for example, use HDL language processing to transform hierarchies such as, for example, to transform from a logical hierarchy into a different physical hierarchy. Such a tool provides the ability to rewrite the VHDL. It provides instructions to direct when to create a level of hierarchy, move a block from one level of hierarchy to another level of hierarchy and create a connection (physical connection) between levels of hierarchy. As an example, start with one large “blob” of VHDL, construct directives for the hierarchy transformation and feed same into the process. That process will output several new pieces of VHDL for those “new” physical hierarchies. That subsequent VHDL is then used to construct the physical design and proceed with the rest of the design process (actual place and routing that will go to manufacturing).

A small block floorplan can be provided with a proposed large block floorplan super-imposed thereon. In a cutting process, the large block floor plan including a number of large bock virtual partitions (continents) obtained via HLBS can be cut out. Each has a new pin assignment in terms of size and/or location. Each HLBS has data including physical abstracts, VHDL entity and timing assertions.

In abutment routing, abutted partitions enable straight routing paths. Ease of use is provided for the second level hierarchy routing problem to avoid contention and so that there is no need to buffer/repeat signals at the top layer of the hierarchy. Routes at the abutment level may contain no circuits (no buffers/repeaters) and a gap will be either non-existent if the pins between partitions actually touch (intersect) or the gap will be small enough that a repeater is unnecessary because it is a wire only level.

Pin assignments can be addressed by timing-constrained global routing and track assignment to establish large block port locations and sizes. Global routing and track assignment can be carried out on a small block model. Global routing enables congestion awareness, while track assignment ensures pins are routed legally and establishes size and location. Port locations can be identified at large block abutted partition boundaries.

Routing congestion can cause zig-zagging across partition boundaries and unneeded ports. A net zig-zags to detour around a congestion region, which creates unnecessary ports with abutted hierarchy flow. In some cases, this issue can be addressed via penalized costs during a multi-commodity flow algorithm. Costs are assigned during the global route resource-sharing algorithm to prevent routes from zig-zagging across partition boundaries. Traversing from the sink to the source along a route, every time that a border is crossed outwardly and then the route goes back in (zig-zagging) is penalized with a high cost. Costs are dynamically updated through the global routing process. The higher the cost, then the multi-commodity flow algorithm will penalize this case and choose a “cheaper” method. Therefore, a subsequent phase of global routing would be forced to route this before other nets and therefore, help avoid detouring against the edge of the partition. Thus, the router is made to be partition-aware (or “continent-aware”). It will eliminate extra crossings that would create going into and out of the same partition multiple times (by the high cost). It will prevent what are known as “short” subways which may cross an edge of a partition needlessly to get from one partition to another (can be visualized by thinking of a corner of the rectangle defining the partition). Furthermore, the router can be guided per net to follow a given pathway.

With the above in mind, a current small-to-large process may not allow for creation of re-used continents.

Turning now to an overview of the aspects of the disclosure, one or more embodiments of the disclosure address the above-described shortcomings of the prior art by providing an IC design with re-use aware routing, the IC design including a hierarchical level having a defined area and multiple logical continent blocks disposed at the hierarchical level and in the defined area. Each one of the multiple logical continent blocks has a common logical layout and represents a re-use instance. A relative floorplan for each re-use instance is the same in terms of placement location and orientation (i.e., re-use instances of logical continent blocks can be mirrored per a user input about an axis extending through the defined area of the hierarchical level).

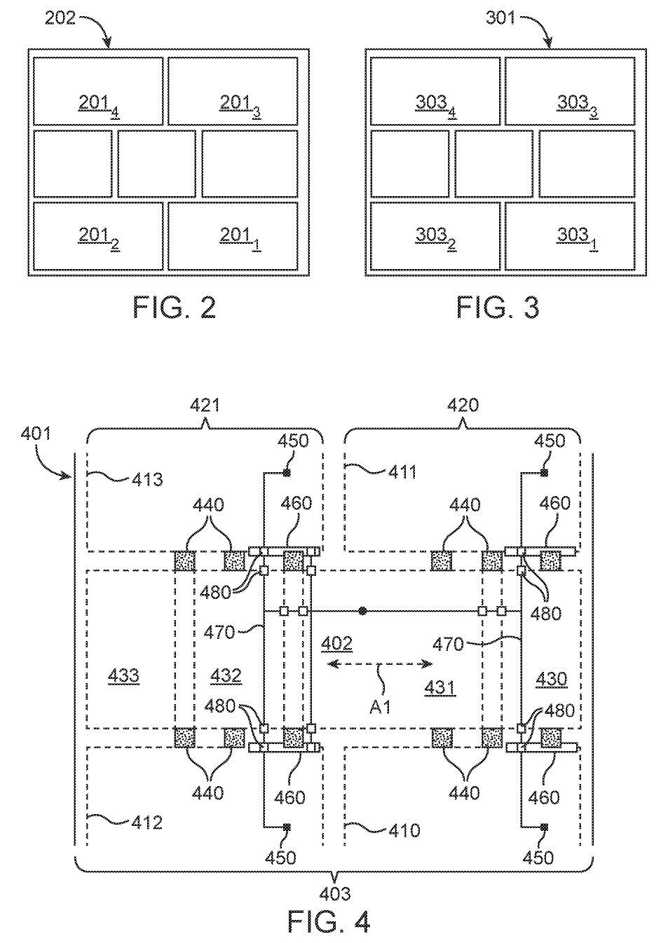

With reference to FIGS. 2 and 3, an IC design 301 (see FIG. 3) with re-use aware routing is provided for EDA employing processes whereby a logical continent block continent can be built once and then re-used multiple times at a given level of a design. That is, whereas a current EDA small-to-large process can create a number (e.g., 7) of unique continents 201₁₋₄ in a given design 202 as shown in FIG. 2, the innovations described herein provide for continents with common logic (hereinafter referred to as “logical continent blocks”) 303₁₋₄to be created once and re-used in the IC design 301 of FIG. 3.

With continued reference to FIG. 3 and with additional reference to FIG. 4, an IC design 401 with re-use aware routing is provided includes a hierarchical level 402 having a defined area 403 and an axis A1 extending through the defined area 403 and multiple logical continent blocks 410, 411, 412 and 413. The multiple logical continent blocks 410, 411, 412 and 413 are disposed at the hierarchical level 402 and in the defined area 403. Each one of the multiple logical continent blocks 410, 411, 412 and 413 has a common logical layout and represents a re-use instance characterized in that a relative floorplan for each re-use instance is the same in terms of placement location and orientation. That is, in certain cases per a user input, each on of the multiple logical continent blocks 410, 411, 412 and 413 can be, but are not required to be, mirrored with respect to another one of the multiple logical continent blocks 410, 411, 412 and 413 about the axis A1. That is, logical continent block 410 can be mirrored with respect to logical continent block 411 about the axis A1 to form a mirrored logical continent block pair 420 and logical continent block 412 can be mirrored with respect to logical continent block 413 about the axis A1 to form a mirrored logical continent block pair 421.

The following description will generally relate to the cases in which the logical continent block 410 is mirrored with respect to the logical continent block 411 about the axis A1 to form a mirrored logical continent block pair 420 and the logical continent block 412 is mirrored with respect to the logical continent block 413 about the axis A1 to form a mirrored logical continent block pair 421. This is being done for purposes of clarity and brevity and should not be interpreted as limiting the description or the following claims in any way.

The IC design 401 can further include additional logical continent blocks 430, 431, 432 and 433 and re-use blockages 440. Each of the additional logical continent blocks 430, 431, 432 and 433 has a distinct logical layout from the common logical layout of the logical continent blocks 410, 411, 412 and 413 and is disposed at the hierarchical level 402 and in the defined area 403 between at least one of the mirrored logical continent block pairs 420 and 421 (e.g., additional logical continent block 430 is between logical continent block 410 and logical continent block 411 of the logical continent block pair 420 and additional logical continent block 433 is between logical continent block 412 and logical continent block 413 of the logical continent block pair 421). The re-use blockages 440 can be arranged between neighboring ones of the multiple logical continent blocks 410, 411, 412 and 413 and the additional logical continent blocks 430, 431, 432 and 433.

Within the IC design 401, each one of the logical continent blocks 410 and 411 in mirrored logical continent block pair 420 and each one of the logical continent blocks 412 and 413 in mirrored logical continent block pair 421 includes a common gate 450 at a same relative position therein and a port interval 460 at a same relative position therein. In these or other cases, the IC design 401 can further include a net 470 and pins 480. The net 470 is routed between the common gate 450 of each one of the multiple logical continent blocks 410 and 411 in mirrored logical continent block pair 420 and between the common gate 450 of each one of the multiple logical continent blocks 412 and 413 in mirrored logical continent block pair 421. The pins 480 are provided in locations that are defined within the port interval 460 of each one of the multiple logical continent blocks 410 and 411 in mirrored logical continent block pair 420 where the net 470 crosses a boundary of each one of the multiple logical continent blocks 410 and 411 and of each one of the multiple logical continent blocks 412 and 413 in mirrored logical continent block pair 421 where the net 470 crosses a boundary of each one of the multiple logical continent blocks 412 and 413.

It is to be understood that, while FIG. 4 includes the common gate 450, each one of the logical continent blocks 410 and 411 and each one of the logical continent blocks 412 and 413 can include multiple common gates 450 and multiple additional gates. Also, while FIG. 4 is illustrated with each net 470 being routed between common gates 450, it is to be understood that this is not required and that other configurations are possible. For example, each net 470 can be connected to a common gate 450 at one end thereof and to a different gate at the other end thereof.

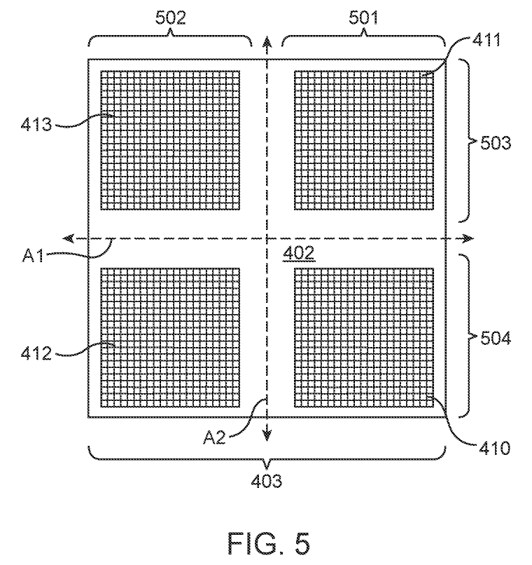

With continued reference to FIGS. 3 and 4 and with additional reference to FIG. 5, the hierarchical level 402 has at least the first axis A1 and a second axis A2, which both extend through the defined area 403 and which are transverse or perpendicular with respect to one another. In these or other cases, the multiple logical continent blocks 410, 411, 412 and 413 can each be provided in at least first mirrored logical continent block pairs 501, 502 mirrored about the first axis A1 and second mirrored logical continent block pairs 503, 504 mirrored about the second axis A2.

It is to be understood that, while the first and second axes A1 and A2 in FIGS. 4 and 5 are illustrated with particular orientations, other orientations of the axes are possible and need not be perpendicular with respect to one another. For example, the first axis A1 in FIG. 4 can be orientated such that logical continent blocks 410 and 412 can be mirrored. As another example, the first axis A1 in FIG. 4 can be oriented into and out of the image (i.e., perpendicular to the hierarchical level 402 in which case logical continent blocks 410 and 413 can be mirrored. In addition, while the embodiments of FIGS. 4 and 5 include two logical continent block pairs, this is not required. For example, while the multiple logical continent blocks 410 and 411 are provided in mirrored logical continent block pair 420, the other logical continent blocks 412 and 413 need not be mirrored.

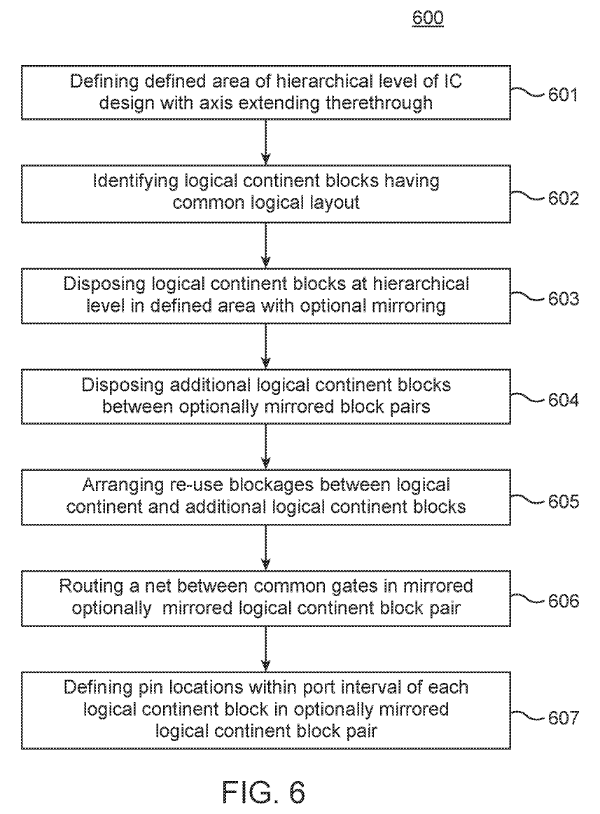

With reference to FIG. 6, a re-use aware routing method 600 is provided for an IC design. The re-use aware routing method 600 includes defining a defined area of a hierarchical level of the IC design with an axis extending therethrough (block 601), identifying multiple logical continent blocks disposable at the hierarchical level and in the defined area and having a common logical layout (block 602) and disposing the multiple logical continent blocks at the hierarchical level and in the defined area with each one of the multiple logical continent blocks having the common logical layout optionally mirrored with respect to another one of the multiple logical continent blocks about the axis (block 603). In addition, the re-use aware routing method 600 can further include disposing additional logical continent blocks, which have a distinct logical layout from the common logical layout, at the hierarchical level and in the defined area between optionally mirrored logical continent block pairs (block 604) and arranging re-use blockages between the multiple logical continent blocks and the additional logical continent blocks (block 605).

Each one of the multiple logical continent blocks in an optionally mirrored logical continent block pair can include a common gate at a same relative position therein and a port interval at a same relative position therein. In these or other cases, the re-use aware routing method 600 can further include routing a net between the common gate of each one of the multiple logical continent blocks in an optionally mirrored logical continent block pair (block 606) and defining pin locations within the port interval of each one of the multiple logical continent blocks in the optionally mirrored logical continent block pair (block 607) where the net crosses a boundary of each one of the multiple logical continent blocks in the optionally mirrored logical continent block pair.

As noted above, the hierarchical level can have at least first and second axes, which extend through the defined area and which are transverse with respect to one another. In these or other cases, the re-use aware routing method 600 can further include providing the multiple logical continent blocks in at least first and second optionally mirrored logical continent block pairs mirrored about the first and second axes, respectively as explained above.

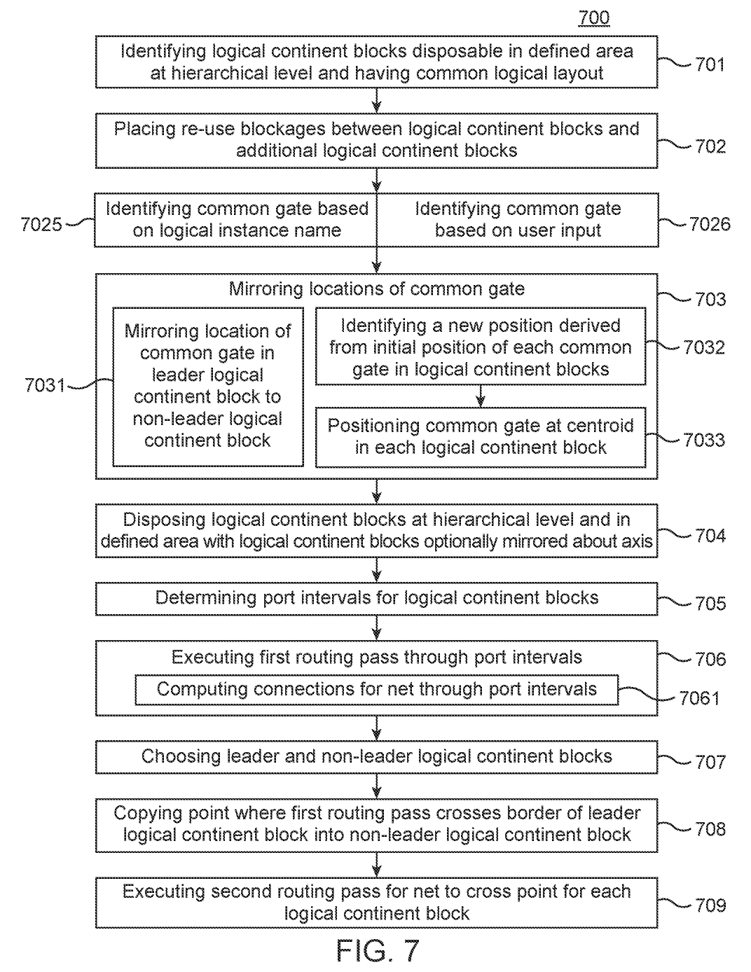

With reference to FIG. 7, a method 700 of re-use aware routing for an IC design is provided. The method 700 initially includes identifying logical continent blocks disposable in a defined area at a hierarchical level and having a common logical layout (block 701), placing re-use blockages between the logical continent blocks and additional logical continent blocks (block 702) and disposing the logical continent blocks at the hierarchical level and in the defined area with the logical continent blocks optionally mirrored about the axis (block 704) to form one of optionally multiple mirrored logical continent block pairs of the IC design. The method 700 further includes determining port intervals for the logical continent blocks (block 705), where the determining of the port intervals of block 705 is executed in order to force certain pin locations for the logical continent blocks. The method 700 also includes executing a first routing pass through the port intervals (block 706) by computing connections for a net through the port intervals (block 7061), choosing leader and non-leader logical continent blocks (block 707), copying a point where the first routing pass crosses a border of the leader logical continent block into the non-leader logical continent block (block 708) and executing a second routing pass for a net to cross the point for each logical continent block (block 709).

Each logical continent block can include a common gate that can be identified based on a logical instance name thereof (block 7025) and/or based on a user input (block 7026), and the method 700 can further include mirroring locations of the common gate (block 703). The mirroring of the locations of the common gate of block 703 can include at least one of mirroring the location of the common gate in the leader logical continent block to the non-leader logical continent block (block 7031) where it is to be understood that the choosing of the leader logical continent block and the non-leader logical continent block of block 707 can be executed in advance of the mirroring of the locations of the common gate of block 703 and identifying a new position derived from initial positions of the common gate in each of the logical continent blocks (block 7032) and positioning the common gate at the new position in each of the logical continent blocks (block 7033). In accordance with one or more embodiments, the new position can be, but is not required to be, a centroid of the initial positions.

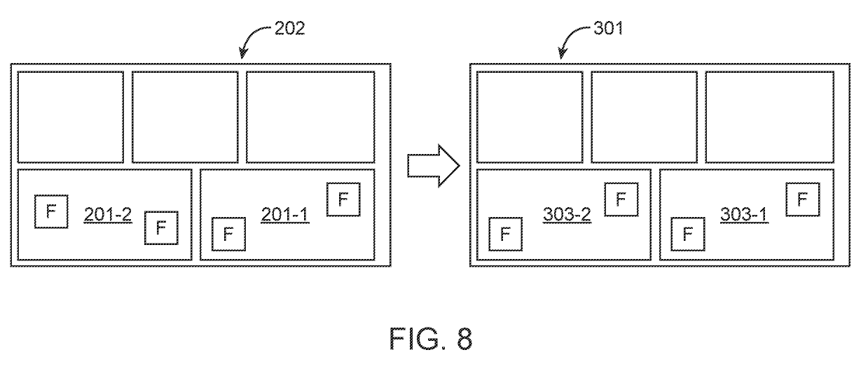

With reference to FIG. 8, the IC design 301 with re-use aware routing and without mirroring is provided for EDA employing processes whereby a logical continent block continent can be built once and then re-used multiple times at a given level of a design. That is, whereas a current EDA small-to-large process can create a number (e.g., 7) of unique continents 201-1 and 201-2 in a given design 202, the innovations described herein provide for logical continent blocks 303-1 and 303-2 to be created once and re-used in the IC design 301. As shown in FIG. 8, while the blocks F (i.e., common gates) in unique continents 201-1 and 201-2 are in different relative positions, the blocks F in the logical continent blocks 303-1 and 303-2 can have transposed relative locations in an event the logical continent blocks 303-1 and 303-2 have a same orientation.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ± 8% or 5%, or 2% of a given value.

For the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of re-use aware routing for an integrated circuit (IC) design, the method comprising:
identifying logical continent blocks disposable in a defined area at a hierarchical level and having a common logical layout;
disposing the logical continent blocks at the hierarchical level and in the defined area;
determining port intervals for the logical continent blocks;
executing a first routing pass through the port intervals;
choosing leader and non-leader logical continent blocks;
copying a point where the first routing pass crosses a border of the leader logical continent block into the non-leader logical continent block; and
executing a second routing pass for a net to cross the point for each logical continent block.

2. The method according to claim 1, wherein the logical continent blocks form one of multiple mirrored logical continent block pairs of the IC design.

3. The method according to claim 1, wherein the determining of the port intervals is executed to force certain pin locations for the logical continent blocks.

4. The method according to claim 3, wherein the executing of the first routing pass comprises computing connections through the port intervals.

5. The method according to claim 1, further comprising placing re-use blockages between the logical continent blocks and additional logical continent blocks.

6. The method according to claim 1, wherein:
each logical continent block comprises a common gate, and
the method further comprises mirroring locations of the common gate.

7. The method according to claim 6, wherein the mirroring of the locations of the common gate comprises mirroring the location of the common gate in the leader logical continent block to the non-leader logical continent block.

8. The method according to claim 6, wherein the mirroring of the locations of the common gate comprises:
identifying a new position derived from initial positions of the common gate in each of the logical continent blocks; and
positioning the common gate at the new position in each of the logical continent blocks.

9. The method according to claim 6, further comprising identifying the common gate based on a logical instance name thereof.

10. The method according to claim 6, further comprising identifying the common gate based on a user input.

11. An integrated circuit (IC) with re-use aware routing, comprising:
a hierarchical level having a defined area;
logical continents at the hierarchical level and in the defined area, each having a common logical layout;
additional logical continents, each having a distinct logical layout from the common logical layout and being disposed at the hierarchical level;
re-use blocks between the logical continents and the additional logical continents;
a net routed to each one of the logical continents; and
pins where the net crosses a boundary of each one of the logical continents.

12. The IC according to claim 11, wherein:
each one of the logical continents in a mirrored logical continent block pair with another one of the logical continents comprises:
a common gate at a same relative position therein; and
a port interval at a same relative position therein,
the net is routed between the common gate of each one of the logical continents in the mirrored logical continent block pair, and
the pins are located within the port interval of each one of the logical continents in the mirrored logical continent block pair.

13. The IC according to claim 12, wherein:
the hierarchical level has at least first and second axes, which extend through the defined area and which are transverse with respect to one another, and
the logical continents are provided in at least first and second mirrored logical continent block pairs mirrored about the first and second axes, respectively.

14. An integrated circuit (IC) design with re-use aware routing, the IC design comprising:
a hierarchical level having a defined area and an axis extending through the defined area; and
multiple logical continent blocks disposed at the hierarchical level and in the defined area,
each one of the multiple logical continent blocks having a common logical layout and being mirrored with respect to another one of the multiple logical continent blocks about the axis.

15. The IC design according to claim 14, further comprising:
additional logical continent blocks, each having a distinct logical layout from the common logical layout and being disposed at the hierarchical level and in the defined area between mirrored logical continent block pairs; and
re-use blockages arranged between the multiple logical continent blocks and the additional logical continent blocks.

16. The IC design according to claim 14, wherein each one of the multiple logical continent blocks in a mirrored logical continent block pair comprises:
a gate at a same relative position therein; and
a port interval at a same relative position therein, and
the IC design further comprises:
a net routed between the gate of each one of the multiple logical continent blocks in a mirrored logical continent block pair; and
pin locations defined within the port interval of each one of the multiple logical continent blocks in the mirrored logical continent block pair where the net crosses a boundary of each one of the multiple logical continent blocks in the mirrored logical continent block pair.

17. The IC design according to claim 14, wherein:
the hierarchical level has at least first and second axes, which extend through the defined area and which are transverse with respect to one another, and
the multiple logical continent blocks are provided in at least first and second mirrored logical continent block pairs mirrored about the first and second axes, respectively.

18. An integrated circuit (IC) design with re-use aware routing, the IC design comprising:
a hierarchical level having a defined area and multiple axes extending through the defined area; and
multiple logical continent blocks disposed at the hierarchical level and in the defined area,
each one of the multiple logical continent blocks having a common logical layout and being mirrored with respect to another one of the multiple logical continent blocks about at least one of the multiple axes.

19. The IC design according to claim 18, further comprising:
additional logical continent blocks, each having a distinct logical layout from the common logical layout and being disposed at the hierarchical level and in the defined area between mirrored logical continent block pairs; and
re-use blockages arranged between the multiple logical continent blocks and the additional logical continent blocks.

20. The IC design according to claim 18, wherein each one of the multiple logical continent blocks in a mirrored logical continent block pair comprises:
a common gate at a same relative position therein; and
a port interval at a same relative position therein, and
the IC design further comprises:
a net routed between the common gate of each one of the multiple logical continent blocks in a mirrored logical continent block pair; and
pin locations defined within the port interval of each one of the multiple logical continent blocks in the mirrored logical continent block pair where the net crosses a boundary of each one of the multiple logical continent blocks in the mirrored logical continent block pair.

21. The IC design according to claim 18, wherein:
the multiple axes comprise at least first and second axes, which extend through the defined area and which are transverse with respect to one another, and
the multiple logical continent blocks are provided in at least first and second mirrored logical continent block pairs mirrored about at least one of the first and second axes, respectively.

22. A re-use aware routing method for an integrated circuit (IC) design, the re-use aware routing method comprising:
defining a defined area of a hierarchical level of the IC design with an axis extending therethrough;
identifying multiple logical continent blocks disposable at the hierarchical level and in the defined area and having a common logical layout; and
disposing the multiple logical continent blocks at the hierarchical level and in the defined area with each one of the multiple logical continent blocks having the common logical layout mirrored with respect to another one of the multiple logical continent blocks about the axis.

23. The re-use aware routing method according to claim 22, further comprising:
disposing additional logical continent blocks, which have a distinct logical layout from the common logical layout, at the hierarchical level and in the defined area between mirrored logical continent block pairs; and
arranging re-use blockages between the multiple logical continent blocks and the additional logical continent blocks.

24. The re-use aware routing method according to claim 22, wherein each one of the multiple logical continent blocks in a mirrored logical continent block pair comprises:
a common gate at a same relative position therein; and
a port interval at a same relative position therein, and
the re-use aware routing method further comprises:
routing a net between the common gate of each one of the multiple logical continent blocks in a mirrored logical continent block pair; and
defining pin locations within the port interval of each one of the multiple logical continent blocks in the mirrored logical continent block pair where the net crosses a boundary of each one of the multiple logical continent blocks in the mirrored logical continent block pair.

25. The re-use aware routing method according to claim 22, wherein:
the hierarchical level has at least first and second axes, which extend through the defined area and which are transverse with respect to one another, and
the re-use aware routing method further comprises providing the multiple logical continent blocks in at least first and second mirrored logical continent block pairs mirrored about the first and second axes, respectively.
